(19) United States
(12) Patent Application Publication
(10) Pub. No.: US 2006/0044912 A1
(43) Pub. Date: Mar. 2, 2006

(54) Method and apparatus for refreshing memory device

(76) Inventors: Byoung-Sul Kim, Suwon-Si (KR); Yun-Sang Lee, Yongin-Si (KR)

Correspondence Address: LAW OFFICE OF MONICA H CHOI, P O BOX 3424, DUBLIN, OH, 430160204, US

(21) Appl. No.: 11/129,073

(22) Filed: May 13, 2005

(30) Foreign Application Priority Data
Aug. 31, 2004 (KR) 2004-69095

(51) Int. Cl. G11C 7/00

(52) U.S. Cl. 365/222

(57) ABSTRACT

For refreshing a memory device, a refresh selection unit is enabled within a selected group of memory cells for refreshing at least one memory cell within the selected group in response to a refresh control signal and a refresh address signal from an external source. In addition, a normal operation circuit performs a normal operation on at least one memory cell of another group of memory cells while the at least one memory cell within the selected group is being refreshed to reduce refresh overhead.

This application claims priority to Korean Patent Application No. 2004-69095, filed on Aug. 31, 2004, in the Korean Intellectual Property Office, the disclosure of which is incorporated herein in its entirety by reference.

### BACKGROUND OF THE INVENTION

1. Field of the Invention

The present invention relates generally to memory devices, and more particularly, to a method and apparatus for refreshing a memory device while simultaneously performing a normal operation on the memory device.

2. Description of the Related Art

In some memory devices such as DRAMs (dynamic random access memories), refreshing memory cell data is indispensable. Hence, all memory cells are refreshed within a predetermined period of time. Without properly refreshing memory cell data, data read is inaccurate because of charge leakage from the memory cells.

As memory capacity increases, the time required to refresh the memory cells of the memory device increases. However, increased time for refreshing the memory cells adversely affects performance of the memory device. More particularly, since refreshing memory cells is typically controlled by a memory controller or the like, the time required for the memory controller to control the refreshing operation may exceed the time required for the memory controller to perform its normal operations (such as read, write, or precharge operations).

FIG. 1 is a block diagram of a DRAM (dynamic random access memory) device 100 that performs a conventional refreshing operation. Referring to FIG. 1, the DRAM 100 includes an address buffer 110, a main decoder 120, and a command decoder 130. The address buffer 110 receives address signals A0 through A13 and BA0 through BA2. The main decoder 120 receives and decodes the address signals A0 through A13 and BA0 through BA2.

The command decoder 130 receives a variety of command signals CS, CAS, RAS, WE, and CKE and produces an active command ACT, a write command WT, a read command RD, a precharge command PREC, and a CBR refresh command CBR_REFRESH. The active command ACT, the write command WT, the read command RD, and the precharge command PREC are provided to a normal operation circuit 140, together with the address signals A0 through A13 and BA0 through BA2 decoded by the main decoder 120, via a normal path.

The normal operation circuit 140 includes circuits for performing normal operations such as a write operation, a read operation, or a precharge operation on memory cells within memory banks of the DRAM device 100. Such normal operations are typical and known to one of ordinary skill in the art of memory devices. In addition, such command signals CS, CAS, RAS, WE, CKE input from an external source are typical and known to one of ordinary skill in the art of memory devices.

The CBR refresh command CBR_REFRESH is provided to a refresh counter 150 for sequentially updating a refresh count. The refresh counter 150 then controls each of N memory banks to be refreshed sequentially as illustrated in FIG. 2. As illustrated in FIG. 3, the DRAM device 100 cannot receive a command other than a refresh command REF during a refresh time tREF. In other words, the DRAM 100 cannot receive a write command WT, a read command RD, or the like during a cycle when a refresh command is being received.

With an increase of the capacity of the DRAM device 100, the time for transmitting a refresh command via the DRAM system bus for sequentially refreshing all memory banks of the DRAM device 100 increases. Accordingly, the DRAM system bus has a refresh overhead. Thus, a memory device capable of refreshing only a selected memory bank and performing a normal operation on another memory bank is desired.

### SUMMARY OF THE INVENTION

Accordingly, memory cells within a selected memory bank are refreshed while a normal operation is simultaneously performed on memory cells of another memory bank to reduce refresh overhead.

In a method and apparatus for refreshing a memory device according to an aspect of the present invention, a refresh selection unit is enabled within a selected group of memory cells for refreshing at least one memory cell within the selected group in response to a refresh control signal and a refresh address signal from an external source. In addition, a normal operation circuit performs a normal operation on at least one memory cell of another group of memory cells while the at least one memory cell within the selected group is being refreshed.

In another embodiment of the present invention, a refresh counter is enabled within the selected group of memory cells for indicating the at least one memory cell to be refreshed within the selected group.

In one embodiment of the present invention, the refresh operation within the selected group of memory cells and the normal operation within another group of memory cells are performed during a same clock cycle.

In another embodiment of the present invention, the memory device is comprised of a plurality of memory banks. In that case, the selected group of memory cells is a selected memory bank, and the another group of memory cells is another memory bank of the plurality of memory banks.

In a further embodiment of the present invention, the normal operation includes one of a read operation, a write operation, or a precharge operation.

In yet another embodiment of the present invention, an external pin of the memory device has the refresh control signal applied thereon. In that case, a refresh command decoder decodes the refresh control signal to determine whether the refresh control signal indicates a refresh mode. In addition, external pins of the memory device have the refresh address signal applied thereon, and the refresh address indicates the selected group of memory cells.

In a further embodiment of the present invention, a command decoder decodes command signals from an external source. Furthermore, a refresh counter controls a plurality of memory banks to be refreshed sequentially in response to the command signals when the memory device is not operating in the refresh mode for refreshing only a selected memory bank.

### BRIEF DESCRIPTION OF THE DRAWINGS

The above and other features and advantages of the present invention will become more apparent when described in detailed exemplary embodiments thereof with reference to the attached drawings in which:

FIG. 1 shows a block diagram of a dynamic random access memory (DRAM) device that performs a conventional refreshing operation;

FIG. 2 illustrates the refreshing operation in the DRAM device of FIG. 1;

FIG. 3 is a timing diagram illustrating the refreshing operation of the DRAM device of FIG. 1;

FIG. 4 shows a block diagram illustrating a refreshing operation according to an embodiment of the present invention;

FIG. 5 shows a block diagram of a memory device which performs the refreshing operation of FIG. 4;

FIG. 6 is a timing diagram illustrating the refreshing operation of the memory device of FIG. 5; and

FIG. 7 shows a block diagram with additional components in the memory device of FIG. 5 for also sequentially refreshing memory banks, according to another embodiment of the present invention.

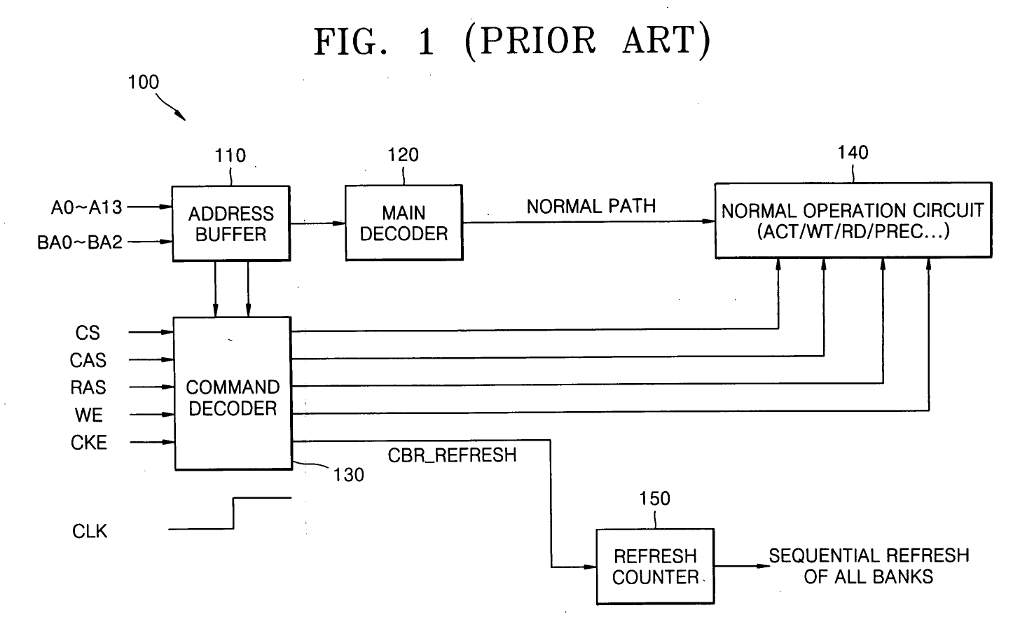

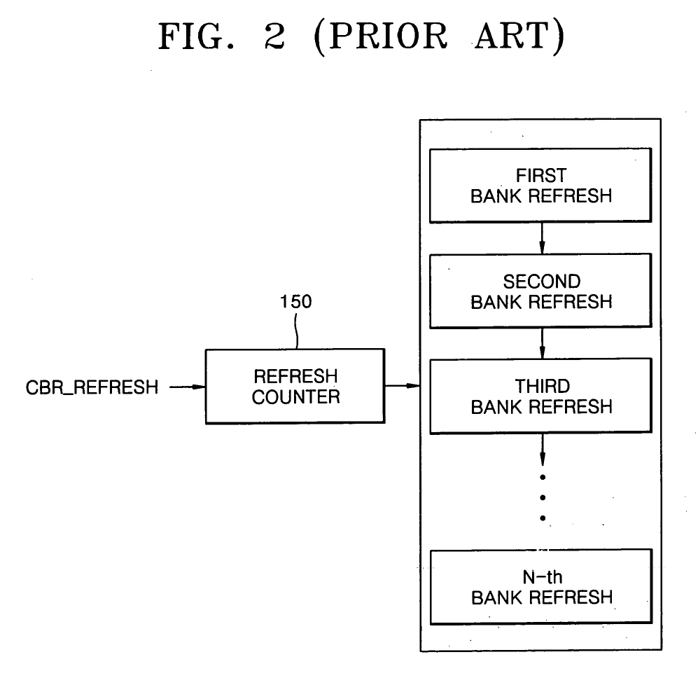

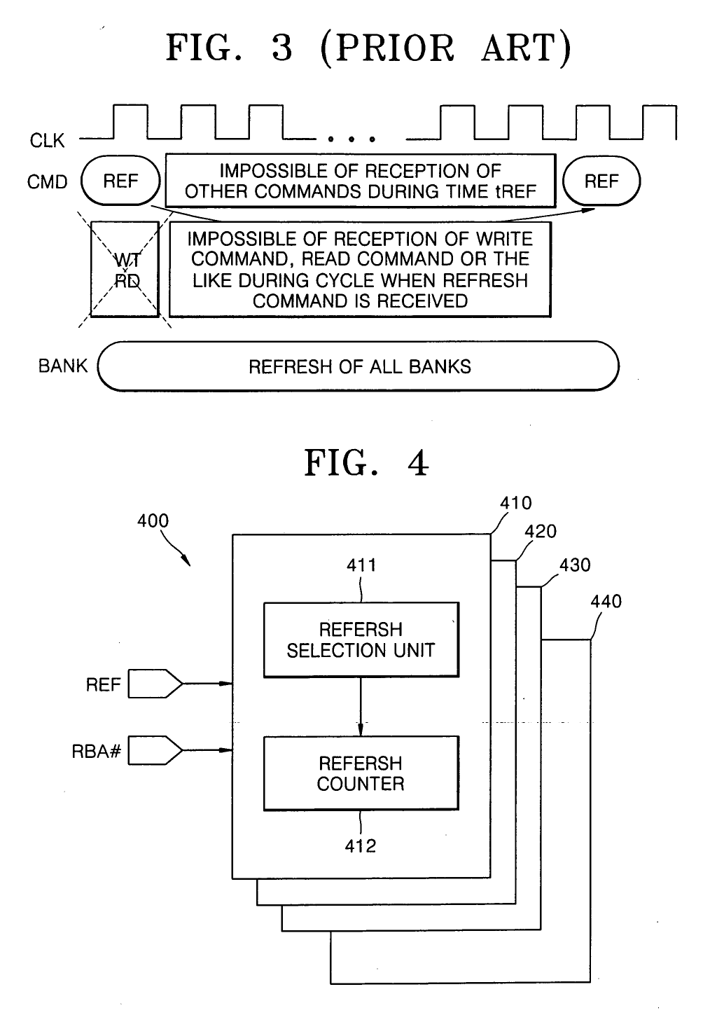

The figures referred to herein are drawn for clarity of illustration and are not necessarily drawn to scale. Elements having the same reference number in FIGS. 1, 2, 3, 4, 5, 6, and 7 refer to elements having similar structure and/or function.

### DETAILED DESCRIPTION OF THE INVENTION

FIG. 4 shows a block diagram for conceptually illustrating a refreshing operation performed by a memory device 400, according to an embodiment of the present invention. Referring to FIG. 4, the memory device 400 enters a refresh mode in response to an external refresh control signal REF input via an external pin of the memory device 400. In addition, the memory device 400 refreshes one of first, second, third, and fourth memory banks 410, 420, 430, and 440 of the memory device 400 in response to an external refresh bank address signal RBA#, which is received in the refresh mode.

In one embodiment of the present invention, the refresh bank address signal is comprised of a plurality of bits RBA0 through RBA2 that are applied on a plurality of external pins of the memory device 400. The refresh control signal REF and the refresh bank address signal are applied on external pins of the memory device 400 from an source external to the memory device 400. The external pins of the memory device 400 are exposed pins of the integrated circuit package holding the integrated circuit die of the memory device 400.

Each of the memory banks 410, 420, 430, and 440 includes a respective refresh selection unit 411 and a respective refresh counter 412. The respective refresh selection unit 411 and the respective refresh counter 412 of a selected one of the memory banks 410, 420, 430, and 440 are enabled such that only the selected memory bank is refreshed. The refresh bank address signal RBA# received at external pins of the memory device 400 indicates the selected one of the memory banks 410, 420, 430, and 440.

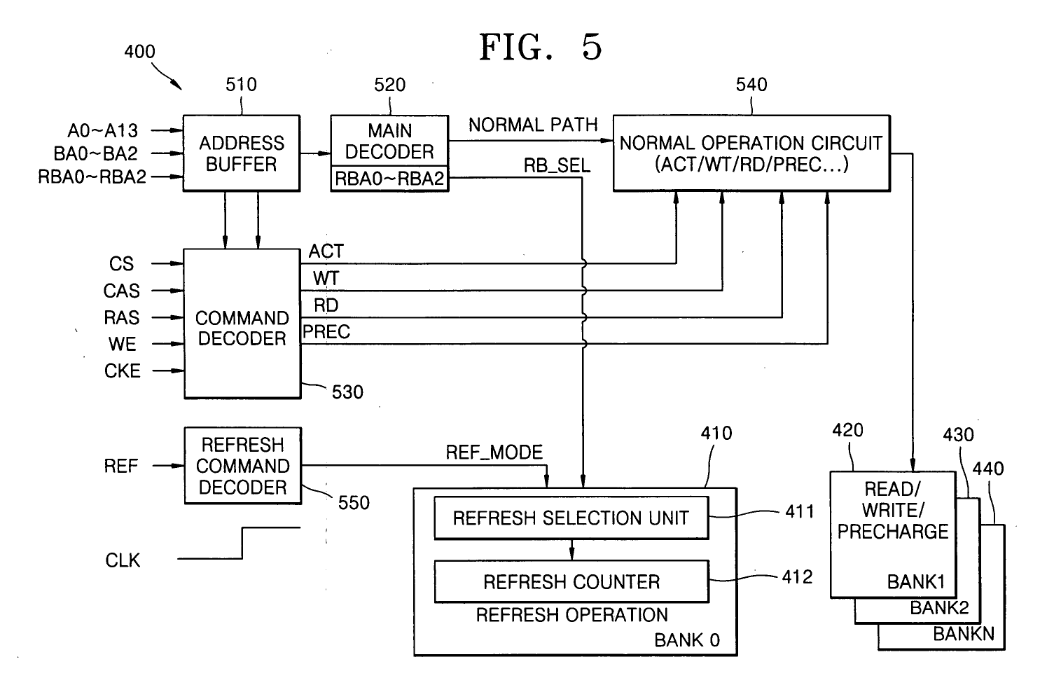

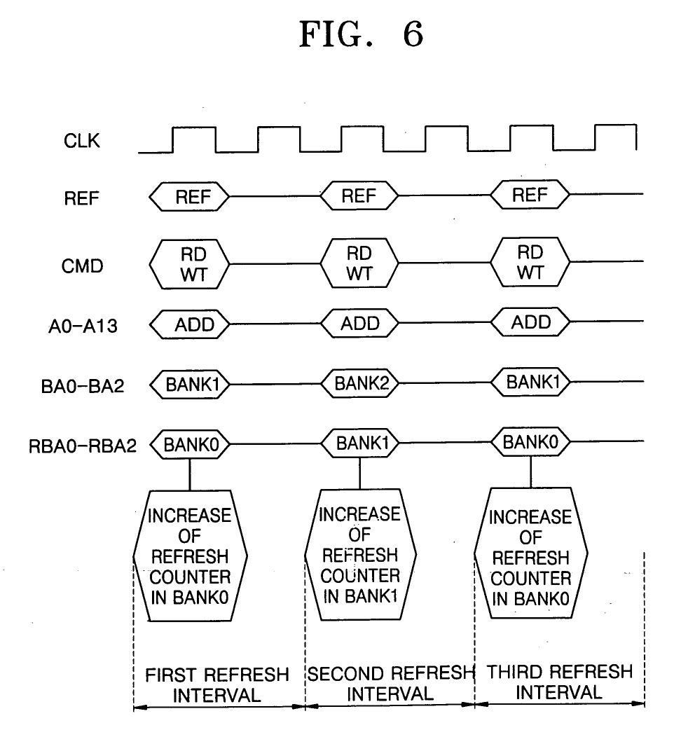

FIG. 5 shows a block diagram of further components of the memory device 400 for performing the refreshing operation according to an embodiment of the present invention. Referring to FIG. 5, the memory device 400 includes an address buffer 510, a main decoder 520, a command decoder 530, a normal operation circuit 540, a refresh command decoder 550, and the first, second, third, and fourth memory banks 410, 420, 430, and 440.

The address buffer 510 receives address signals A0 through A13, bank address signals BA0 through BA2, and refresh bank address signals RBA0 through RBA2 and provides the same to the main decoder 520. The main decoder 520 decodes the address signals A0 through A13 and the bank address signals BA0 through BA2 to provide decoded signals to the normal operation circuit 540 via a normal path.

Also, the main decoder 520 decodes the refresh bank address signals RBA0 through RBA2 to generate a refresh bank selection signal RB_SEL. The refresh bank selection signal RB_SEL indicates a selected one of the first, second, third, and fourth banks 410, 420, 430, and 440. The command decoder 530 receives a variety of command signals CS, CAS, RAS, WE, and CKE to generate an active command ACT, a write command WT, a read command RD, or a precharge command PREC that is provided to the normal operation circuit 540.

The refresh command decoder 550 receives the external refresh control signal REF from an external pin of the memory device 400 to generate a refresh mode signal REF_MODE. The refresh mode signal REF_MODE indicates whether the memory device 400 is to operate in a refresh mode for refreshing a selected memory bank.

For example, assume that the refresh mode signal REF_MODE is activated to indicate that the memory device 400 is to operate in such a refresh mode. In addition, assume that the refresh bank selection signal RB_SEL indicates that the first memory bank 410 is the selected one of the memory banks 410, 420, 430, and 440 to be refreshed. In that case, the respective refresh selection unit 411 within the first memory bank 410 is enabled, and the respective refresh counter 412 within the first memory bank 410 is updated by +1. Accordingly, wordlines within the first memory bank 410 corresponding to an address as indicated by the refresh counter 412 are activated, thereby refreshing memory cells within the first memory bank 410.

While such memory cells are being refreshed within the first memory bank 410, a normal operation may be performed in any of the second, third, and fourth memory banks 420, 430, and 440. Such a normal operation includes a write, read, or precharge operation performed by the normal operation circuit 540 in response to any of the active command ACT, the write command WT, the read command RD, or the precharge command PREC from the command decoder 530.

Referring to FIG. 7, the memory device 400 may also perform an alternative refresh operation whereby all of the first, second, third, and fourth memory banks 410, 420, 430, and 440 are refreshed sequentially in response to a CBR refresh control signal received from the command decoder 530. Similar to the memory device 100 of FIG. 1, the memory device 400 of FIGS. 5 and 7 also includes a refresh counter 590 that controls the memory banks 410, 420, 430, and 440 to be sequentially refreshed.

In that case, the REF_MODE signal is deactivated such that one of the memory banks 410, 420, 430, and 440 is not selectively refreshed. Instead, the CBR_REFRESH signal is activated in response to the command signals CS, CAS, RAS, WE, and CKE received at the command decoder 530. With activation of the CBR_REFRESH signal, the refresh counter 590 is incremented sequentially such that the memory banks 410, 420, 430, and 440 are sequentially refreshed.

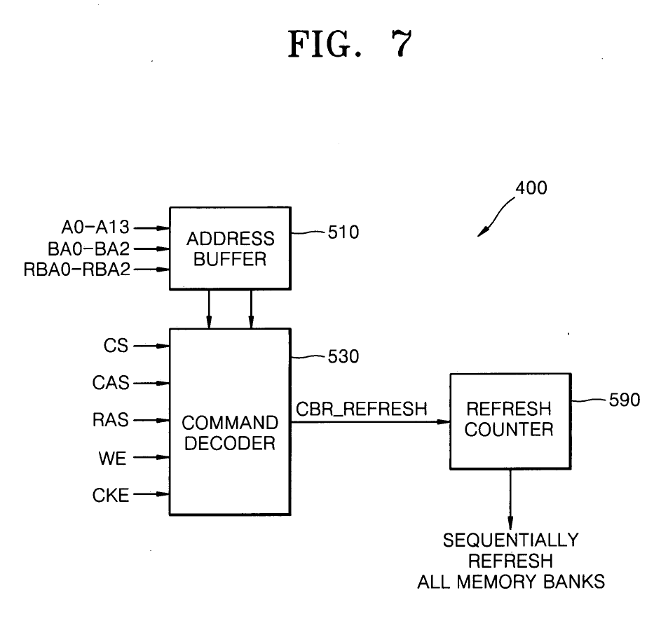

FIG. 6 shows a timing diagram during operation of the memory device 400 of FIG. 5 when the refresh mode signal REF_MODE is activated to indicate that the memory device 400 is to operate in the refresh mode for refreshing a selected memory bank. Referring to FIG. 6, the refresh control signal REF is received via an external pin in synchronization with a clock signal CLK. In addition, a read/write command RD or WT is generated by the command decoder 530 from the command signals CS, CAS, RAS, WE, and CKE.

In the example of FIG. 6, the bank address signals BA0 through BA2 indicate that a read/write command (RD or WT) is to be performed sequentially for the second memory bank BANK1, and then the third memory bank BANK2, and then the second memory bank BANK1 as indicated by the address signals A0 through A13. In addition, the refresh bank address signals RBA0 through RBA2 indicate that the memory banks are to be refreshed sequentially in an order of the first memory bank BANK0, and then the second memory bank BANK1, and then the first bank memory BANK0.

Further referring to FIG. 6, during a first clock cycle for a first refresh interval, at least one memory cell is refreshed within the first memory bank BANK0 as indicated by the refresh counter 412 within the first memory bank BANK0 that is the selected memory bank. Also during such a first refresh interval, a reading/writing operation is performed on at least one memory cell within the second memory bank BANK1.

Subsequently during a second clock cycle for a second refresh interval, at least one memory cell is refreshed within the second memory bank BANK1 as indicated by the refresh counter 412 within the second memory bank BANK1 that is the selected memory bank. Also during such a second refresh interval, a reading/writing operation is performed on at least one memory cell within the third memory bank BANK2.

Thereafter during a third clock cycle for a third refresh interval, at least one memory cell is refreshed within the first memory bank BANK0 as indicated by the refresh counter 412 within the first memory bank BANK0 that is the selected memory bank. Also during such a third refresh interval, a reading/writing operation is performed on at least one memory cell within the second memory bank BANK1.

In this manner, while refreshing a selected memory bank in response to the external refresh control signal REF and the refresh bank address signals RBA0 through RBA2, the memory device 400 also performs a normal operation on any of the remaining memory banks. Therefore, refresh overhead is reduced with the present invention.

While the present invention has been particularly shown and described with reference to exemplary embodiments thereof, it will be understood by those of ordinary skill in the art that various changes in form and details may be made therein without departing from the spirit and scope of the present invention as defined by the following claims. For example, the memory device 400 has been illustrated and described as being organized to memory banks. However, the present invention may be generalized to organization of the memory device 400 into any other types of groups of memory cells.

What is claimed is:

1. A method of refreshing a memory device, comprising:
A. enabling a refresh selection unit for a selected group of memory cells for refreshing at least one memory cell of the selected group in response to a refresh control signal and a refresh address signal from an external source; and
B. performing a normal operation on at least one memory cell of another group of memory cells while performing step A.

2. The method of claim 1, wherein steps A and B are performed during a same clock cycle.

3. The method of claim 1, wherein the memory device is comprised of a plurality of memory banks, and wherein the selected group of memory cells is a selected memory bank, and wherein said another group of memory cells is another memory bank of the plurality of memory banks.

4. The method of claim 1, wherein the normal operation includes one of a read operation, a write operation, or a precharge operation.

5. The method of claim 1, further comprising:
receiving the refresh control signal applied at an external pin of the memory device; and
performing steps A and B when the refresh control signal indicates a refresh mode.

6. The method of claim 5, further comprising:
not performing steps A and B when the refresh control signal does not indicate the refresh mode; and
refreshing a plurality of memory banks of the memory device sequentially in response to command signals received by the memory device.

7. The method of claim 1, further comprising:
receiving the refresh address signal at external pins of the memory device, wherein the refresh address signal indicates the selected group of memory cells.

8. An apparatus for refreshing a memory device, comprising:
a refresh selection unit that is enabled within a selected group of memory cells for refreshing at least one memory cell within the selected group in response to a refresh control signal and a refresh address signal from an external source; and
a normal operation circuit for performing a normal operation on at least one memory cell of another group of memory cells while the at least one memory cell within the selected group is being refreshed.

9. The apparatus of claim 8, wherein the refresh operation within the selected group and the normal operation within said another group are performed during a same clock cycle.

10. The apparatus of claim 8, wherein the memory device is comprised of a plurality of memory banks, and wherein the selected group of memory cells is a selected memory bank, and wherein said another group of memory cells is another memory bank of the plurality of memory banks.

11. The apparatus of claim 8, wherein the normal operation includes one of a read operation, a write operation, or a precharge operation.

12. The apparatus of claim 8, further comprising:
an external pin having the refresh control signal applied thereon; and
a refresh command decoder that decodes the refresh control signal to determine whether the refresh control signal indicates a refresh mode.

13. The apparatus of claim 12, further comprising:
a command decoder for decoding command signals from an external source; and
a refresh counter that controls a plurality of memory banks to be refreshed sequentially in response to the command signals.

14. The apparatus of claim 8, further comprising:
external pins having the refresh address signal applied thereon, wherein the refresh address signal indicates the selected group of memory cells.

15. The apparatus of claim 8, further comprising:
a refresh counter that is enabled within the selected group of memory cells for indicating the at least one memory cell to be refreshed within the selected group.

16. A memory device, comprising:
a plurality of memory banks, each memory bank having a respective refresh selection unit and a respective refresh counter that are enabled for a selected memory bank for refreshing at least one memory cell within the selected memory bank in response to a refresh control signal and a refresh address signal from an external source; and
a normal operation circuit for performing a normal operation on at least one memory cell in another memory bank while the at least one memory cell within the selected memory bank is being refreshed.

17. The memory device of claim 16, wherein the refresh operation within the selected memory bank and the normal operation within said another memory bank are performed during a same clock cycle.

18. The memory device of claim 16, wherein the normal operation includes one of a read operation, a write operation, or a precharge operation.

19. The memory device of claim 16, further comprising:
an external pin having the refresh control signal applied thereon;
a refresh command decoder that decodes the refresh control signal to determine whether the refresh control signal indicates a refresh mode; and
external pins having the refresh address signal applied thereon, wherein the refresh address signal indicates the selected memory bank.

20. The memory device of claim 19, further comprising:
a command decoder for decoding command signals from an external source; and
a refresh counter the controls the memory banks to be refreshed sequentially in response to the command signals.
